(19) United States
(12) Patent Application Publication
(10) Pub. No.: US 2002/0084721 A1
(43) Pub. Date: Jul. 4, 2002

(54) Piezo electric keypad assembly with tactile feedback

(76) Inventor: Thomas J. Walczak, Woodstock, IL (US)

Correspondence Address: Motorola, Inc., Personal Communications Sector, Intellectual Property Department (HDW), 600 North US Highway 45, Rm. AN475, Libertyville, IL, 60048, US

(21) Appl. No.: 09/753,811

(22) Filed: Jan. 3, 2001

(51) Int. Cl. H01L 41/04

(52) U.S. Cl. 310/339; 310/318

(57) ABSTRACT

This invention is a keypad assembly (100) for a portable communication device having a plurality of piezoelectric keys (110) to receive user input and providing tactile feedback to the user in response to such user input. The keypad assembly (100) includes one or more keys in which each key (110) has a piezoelectric layer (210), a conductive layer (220) on one side of the piezoelectric layer and another conductive layer (230) on the other side of the piezoelectric layer. The keypad assembly (100) also includes an electronic circuit (120) coupled to the conductive layers (220, 230) of each key (110). When the electronic circuit (120) receives a selection signal from a particular key (110) of the keypad assembly (100), the electronic circuit provides a feedback signal to the particular key in response.

### FIELD OF THE INVENTION

The present invention relates generally to the field of user interfaces for portable electronic devices. In particular, the present invention relates to a wireless communication device having the capability of providing feedback to a user in response to user input to a keypad or touch pad.

### BACKGROUND OF THE INVENTION

Keypads for portable electronic devices are typically constructed from multiple layers of components. A typical keypad may include a membrane layer, a popple layer and a printed circuit board. The membrane layer is the outermost layer that includes a plurality of user accessible keys. The popple layer lies beneath the keypad layer and provides tactile feedback to the user when each key of the keypad layer is depressed. The printed circuit board lies beneath the popple layer and includes a conductive pattern on its top surface. The portable electronic device detects that a key has been selected when the popple layer shorts together multiple lines of the printed circuit board as the membrane layer is depressed against the popple layer.

Unfortunately, keypads having a popple layer for tactile feedback require excessive keypad depth and take-up valuable space in portable electronic devices. The mechanical feedback of a popple layer is provided to the user at the expense of adding height to the keypad. Size and weight are critical commodities for a portable electronic device, so it is disadvantageous for the device to have a popple layer. In addition, the added popple layer may necessitate mechanical alignment and support.

Many portable electronic devices also have piezoelectric layers to provide certain functions to the devices due to their special properties. Piezoelectric materials are advanced industrial materials that, by virtue of their poor electrical conductivity, are useful in the production of electrical storage or generating devices. Specifically, piezoelectric materials may change their dimensions when subjected to an electrical field. Conversely, piezoelectric materials may generate electrical charges when mechanically deformed. Due to this characteristic, piezoelectric materials are commonly used for a variety of electric devices includes those devices that have a user interface. Such user interfaces includes keyboards, keypads, touch pads and the like.

A piezoelectric layer may be used to detect contact of a particular key by a user. As stated above, a piezoelectric material generates a voltage when it is subjected to mechanical pressure and, thus, has practical use for portable electronic devices. A user interface of a portable electronic device may include a plurality of piezoelectric switches that provide input signals to a main circuit of the device. Each switch may correspond to a particular alphanumeric character, such as “1” through “0”, “*”, “#”, “A” through “Z” and “a” through “z”, or operable function of the device. One example of the above piezoelectric switch is a poppel dome and a piezo polymer film laminated on both sides of the poppel dome. The piezo film generates an electrical charge proportional to a change in mechanical stress caused by pressure from a user's finger. This electrical charge is carried away by electrical conductors that overlay the corresponding area of the piezo film touched by the finger. Accordingly, the main circuit of the device is able to receive input from the user via the piezoelectric switches of the user interface.

Piezoelectric materials also have other applications for portable electronic devices. As stated above, piezoelectric materials may exhibit a change in dimension when subjected to an electromagnetic field. A portable electronic device may include a piezoelectric transducer to emit audio sounds to a user. For example, the main circuit of the device may send an electrical signal to the piezoelectric transducer to cause an audible “beep” to be produced by the piezoelectric material. The electrical signal from the main circuit causes the piezoelectric transducer to act as an audio speaker.

Such piezoelectric transducers may also be used to provide audio feedback to a user when the user presses a key on a portable electronic device. When the user presses the key, the main circuit of the device receives an input signal from the corresponding piezoelectric switch. In response, the main circuit sends an electrical pulse to the piezoelectric transducer to produce an audible “click” to be heard by the user. In effect, the portable electronic device is providing an audio acknowledgment to the user indicating that the key has been activated.

Audio feedback for a user interface does not perform well in all conditions. The user may not be able to hear audio feedback in a noisy environment. This problem frequently occurs for a portable electronic device which is used in many public places, such as busy roadways, shopping areas, restaurants, business offices, entertainment venues, and the like, where the general audio level may be particularly high. Although the audio feedback may be set to a louder volume level, this loud audio feedback may be disturbing to the user as well as people near the user. In addition, users may also prefer a quiet environment to operate their portable electronic devices and, thus, dislike the sound of audio feedback. Further, people who are hearing-impaired will not be able to benefit from audio feedback. Therefore, there is a need for a feedback system for a user interface that has minimal space requirements and, preferably, is useable in noisy environments, by those users who prefer a quiet environment and/or by the hearing-impaired.

### BRIEF DESCRIPTION OF THE DRAWINGS

FIG. 1 is a top plan view of a keypad assembly of the present invention;

FIG. 2 is a side sectional view of the keypad assembly taken along line 2-2 of FIG. 1;

FIG. 3 is a circuit diagram of the preferred embodiment of the present invention;

FIG. 4 is a circuit diagram of a first alternative embodiment of the present invention; and

FIG. 5 is a circuit diagram of a second alternative embodiment of the present invention.

### DETAILED DESCRIPTION OF THE PREFERRED EMBODIMENT

The present invention is a keypad assembly for a portable communication device having a plurality of piezoelectric keys to receive user input and providing tactile feedback to the user in response to such user input. The keypad assembly includes one or more keys in which each key has a piezoelectric layer, a conductive layer on one side of the piezoelectric layer and another conductive layer on the other side of the piezoelectric layer. The keypad assembly also includes an electronic circuit coupled to the conductive layers of each key. When the electronic circuit receives a selection signal from a particular key of the keypad assembly, the electronic circuit provides a feedback signal to the particular key in response.

The present invention is a keypad assembly that may be applied to any type of keyboard or keypad for an electronic device. The keypad assembly is particularly useful for portable electronic devices, particularly wireless communication devices, due to the minimal space requirements of the keypad assembly as well as its tactile feedback capabilities as will be described below. However, it is to be understood that the keypad assembly of the present invention may be used for any type of keyboard or keypad assembly in which user input and tactile feedback are desirable.

Referring to FIG. 1, the keypad assembly 100 of the present invention includes a plurality of keypad elements or keys 110 for user interaction. The keypad assembly 100 is part of a portable electronic device (not shown) and operates as a user interface for the device, such as a numeric keypad of a radiotelephone. A user interacts with the keypad assembly 100 by pressing the keys 110 of the keypad assembly in a particular sequence are required for operation of the device. Although the user can generally sense when his or her finger contacts a particular key 110 of the keypad assembly 100, the user will recognize when the device accepts the key selection by the mechanical movement or feedback of the particular key as described herein.

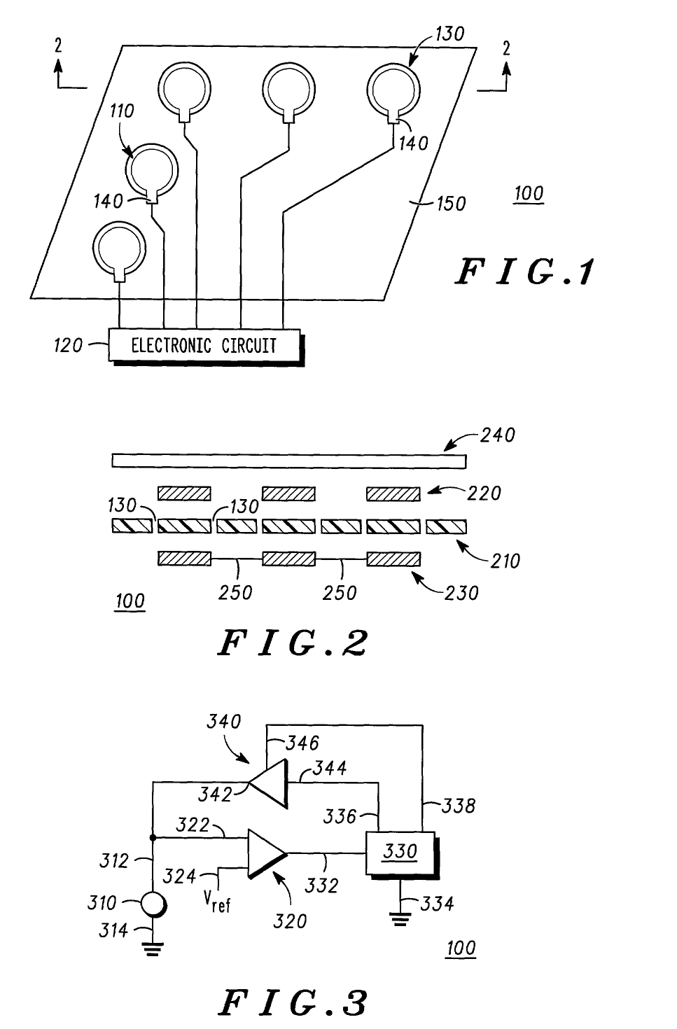

Referring to FIG. 2, each key 110 of the keypad assembly 100 of the preferred embodiment includes a piezoelectric layer 210, an upper conductive layer 220 formed above the piezoelectric layer, a lower conductive layer 230 formed below the piezoelectric layer, and a membrane layer 240 formed above the upper conductive layer. The piezoelectric layer 210 includes a piezoelectric material that generates electrical charges when mechanically deformed and changes dimensions when subjected to an electrical field. The upper and lower conductive layers 220 and 230 include a metallic element that is capable of conducting electrical signals to and from the respective key 110. The lower conductive layer 230 has one or more common conductors 250 that interconnects the plurality of keys 110 and collectively connect them to an electronic circuit 120, shown in FIGS. 1 and 3 through 5 and described below. The upper conductive layer 220 of each key 110 may also include a top side pattern to define the key location. The membrane layer 240 is adhered to the top of the keys 110 to protect the upper surface of the keypad assembly 100. This membrane may also include the keypad graphics such as alphanumeric designations for a particular key 110 or a graphic image representing a function initiated by selecting the key.

Referring to both FIGS. 1 and 2, material 130 of the piezoelectric layer 210 around each key 110 is removed to allow the respective key to generate a mechanical motion in response to a key selection by a user. A connecting portion 140 of each key 110 remains on the keypad 100 to support the key in its appropriate location. For the preferred embodiment shown in FIG. 1, the connecting portions 140 of each key 110 are supported by parts of the piezoelectric layer 150 that are not positioned within an area designated for a key 110. Each connecting portion 140 also provides a conductive path for the upper and lower conductive layers 220, 230 so that the upper conductive layer of each key may individually connect to the electronic circuit 120 and the lower conductive layer of each key may collectively connect to the electronic circuit, described below. As shown in FIG. 1, the upper conductive layer 220 of each key 110 is connected to one end of a conductive line 160. The other end of each conductive line 160 is connected to the electronic circuit 120. In contrast, the lower conductive layers 230 of the keys 110 are interconnected to each other as well as the electronic circuit 120.

Referring to the circuit diagram of FIG. 3, the preferred embodiment of the present invention includes a piezoelectric transducer 310, a comparator 320, a processor 330 and a tristate driver 340. One end 312 of the piezoelectric transducer 310 is coupled to a first input 322 of the comparator 320 and an output 342 of the tristate driver 340, and the other end 314 of the piezoelectric transducer is coupled to ground. Upon activation of the piezoelectric transducer 310, an electric potential is created across the piezoelectric transducer, thereby sending a selection signal to the first input 322 of the comparator 320. The comparator 320 compares this selection signal at the first input 322 to a reference voltage Vref at a second input 324. If the comparator 320 determines that the difference between selection signal created by the piezoelectric transducer 310 and the reference voltage Vref is greater than a predetermined threshold value, then the comparator provides a response signal, such as a voltage spike, to an input 332 of the processor 330. The processor 330 also has a connection 334 coupled to ground. Upon receiving the response signal; the processor knows that the piezoelectric transducer has been activated.

The processor 330 is also coupled to first and second inputs 344, 346 of the tristate driver 340. The first input 344 of the tristate driver 340 receives a feedback signal from a first output 336 of the processor 330, and the second input 346 of the tristate driver receives an activation signal from a second output 338 of the processor. The feedback signal may take a variety of different forms, such as a steady state form that causes a displacement of the piezoelectric transducer or an alternating form that causes the piezoelectric transducer to vibrate. For the preferred embodiment, the feedback signal is a sine wave. When the piezoelectric transducer 310 is not activated, the tristate driver 340 is in its high impedance state. On the other hand, when the piezoelectric transducer 310 is activated, the processor 330 responsively provides the activation signal to the second input 346 of the tristate driver 340. In response, the tristate driver 340 goes to its low impedance state and applies a stimulus signal from its output 342 to one end 312 of the piezoelectric transducer 310 to provide a tactile feedback to the user.

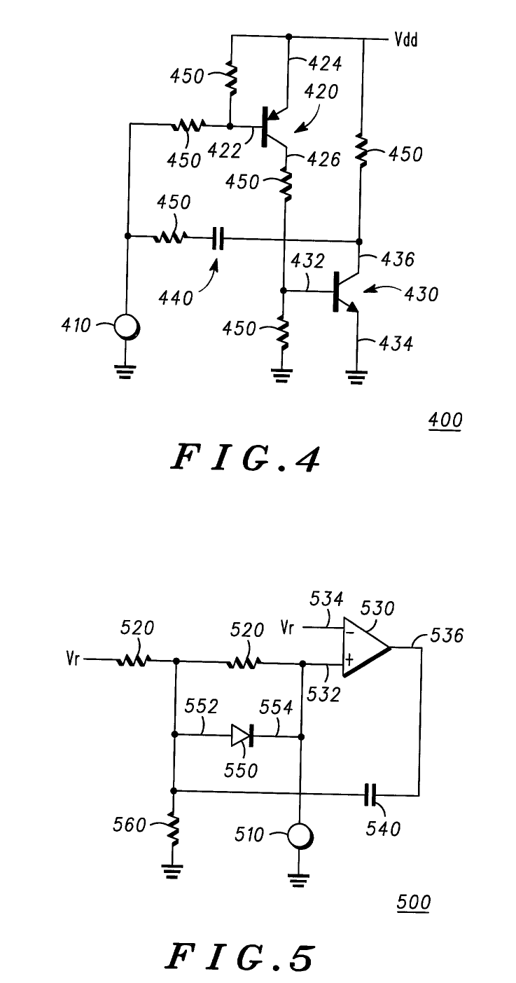

Referring to the circuit diagram of FIG. 4, a first alternative embodiment 400 of the present invention is shown. This first alternative embodiment 400 includes a piezoelectric transducer 410, a PNP transistor 420, an NPN transistor 430, a capacitor 440 and various resistors 450. When the piezoelectric transducer 410 is mechanically deformed by a key press, it generates a current flow to the base 422 of the PNP transistor 420. The emitter 424 of the PNP transistor 420 is connected to a power source Vdd, and the current flow at the base 422 produces a current at the collector 426 of the PNP transistor 420, which drives the base 432 of the NPN transistor 430. The emitter 434 of the NPN transistor 430 is connected to ground, and so the current at the base 432 produces a current at the collector 436 of the NPN transistor 430, which is transferred back to the base 422 of the PNP transistor 420 through the capacitor 440. Energy is also supplied back into the piezoelectric transducer 410 through the capacitor 440 and, thus, causes a mechanical deformation of the piezoelectric transducer, which shall be perceived by the user as tactile feedback. Once the capacitor 440 is fully charged, the current stops flowing in the loop, both transistors 420, 430 turn off, and the capacitor 440 discharges through the various resistors. The cycle is then ready to repeat.

Referring to the circuit diagram of FIG. 5, the second alternative embodiment 500 of the present invention is shown. This second alternative embodiment 500 includes a piezoelectric transducer 510, a voltage divider 520, an operational amplifier 530, a capacitor 540, a diode 550 and another resistor 560. The positive terminal 532 of the operational amplifier 530 is connected to a reference voltage Vr through the voltage divider 520, and the negative terminal 534 of the operational amplifier is connected directly to the reference voltage Vr. In the quiescent state, the resistor divider 520 from reference voltage Vr to ground biases the positive terminal 532 at a lower voltage than the negative terminal 534, thus causing the operational amplifier output 536 to go low. When the piezoelectric transducer 510 is mechanically deformed by a key press, it generates a voltage at the positive terminal 532 that is higher than the reference voltage Vr at the negative terminal 534, thus causing the output 536 of the operational amplifier to go high. The output 536 of the operational amplifier 530 is connected to the piezoelectric transducer 510 through the capacitor 540 and the diode 550. In particular, the input 552 of the diode 550 is connected to the capacitor 540, and the output 554 of the diode is connected to the piezoelectric transducer 510. The capacitor 540 transfers the output voltage of the operational amplifier 530 to the piezoelectric transducer 510 through the diode 550 producing tactile feedback. This output voltage of the operational amplifier 530 also causes the positive terminal 532 to remain high until the capacitor 540 charges. After the capacitor 540 is charged, the output 536 of the operational amplifier 530 goes low, and the capacitor 540 discharges. The cycle is then ready to repeat.

Accordingly, for each key of the above described keypad assembly, piezoelectric material is used to sense a key press and drive a signal to provide tactile feedback in response to the key press. Using the piezoelectric material in this manner minimizes the number of elements to the keypad necessary to provide these features so that the portable electronic device may have a flat, thin keypad structure. In addition, the piezoelectric material provides feedback to the user in various conditions, such as in a noisy environment, by those users who prefer a quiet environment and by the hearing-impaired.

While the preferred embodiments of the invention have been illustrated and described, it is to be understood that the invention is not so limited. Numerous modifications, changes, variations, substitutions and equivalents will occur to those skilled in the art without departing from the spirit and scope of the present invention as defined by the appended claims.

What is claimed is:

1. A keypad assembly for a portable communication device comprising:
at least one key having a piezoelectric layer, a first conductive layer on one side of said piezoelectric layer and a second conductive layer on another side of said piezoelectric layer; and
an electronic circuit coupled to said first and second conductive layers of said at least one key, said electronic circuit being effective to provide a stimulus signal to said at least one key in response to receiving a selection signal from said at least one key.

2. The keypad assembly of claim 1, wherein said first conductive layer includes a plurality of conductive pads individually connected to said electronic circuit.

3. The keypad assembly of claim 1, wherein said second conductive layer includes a plurality of conductive pads interconnected to each other and collectively connected to said electronic circuit.

4. The keypad assembly of claim 1, further comprising a membrane layer on a side of said first conductive layer opposite said piezoelectric layer.

5. The keypad assembly of claim 1, wherein said at least one key includes a plurality of keys and said electronic circuit provides a different stimulus signal to each of said plurality of keys.

6. The keypad assembly of claim 1, wherein said electronic circuit includes a comparator to produce a response signal after comparing said selection signal to a reference signal and determining that a particular key said at least one key has been activated.

7. The keypad assembly of claim 6, wherein said electronic circuit includes a driver to send said stimulus signal to said particular key after said comparator has determined that said particular key has been activated.

8. The keypad assembly of claim 7, wherein said electronic circuit includes a processor capable of sending a feedback signal and an activation signal to said driver, said driver being effective to forward said feedback signal to said particular key in response to receiving said activation signal.

9. The keypad assembly of claim 1, wherein said electronic circuit detects a current pulse from a mechanical deformation of said at least one key.

10. The keypad assembly of claim 1, wherein said electronic circuit provides a current pulse to said at least one key to cause a mechanical deformation of said at least one key.

11. The keypad assembly of claim 1, wherein said electronic circuit includes first and second transistors, said first transistor having a collector being effective to drive a base of said second transistor.

12. The keypad assembly of claim 11, wherein said electronic circuit includes a capacitor positioned between said at least one key and a collector of said second transistor, said capacitor being effective to control current flow to said at least one key.

13. The keypad assembly of claim 1, wherein said electronic circuit includes an operational amplifier and a diode connected in series with said operational amplifier.

14. The keypad assembly of claim 13, wherein said electronic circuit includes a capacitor positioned between said operational amplifier and said diode, said capacitor being effective to control current flow from said diode to said at least one key.
